(19) United States
(12) Patent Application Publication
(10) Pub. No.: US 2014/0048137 A1
(43) Pub. Date: Feb. 20, 2014

(54) Process for preparing coated substrates and photovoltaic devices

(71) Applicants: Yanyan Cao, Wilmington, DE (US); Lynda Kaye Johnson, Wilmington, DE (US); Meijun Lu, Hockessin, DE (US); Irina Malajovich, Swarthmore, PA (US); Daniela Rodica Radu, Hockessin, DE (US)

(72) Inventors: Yanyan Cao, Wilmington, DE (US); Lynda Kaye Johnson, Wilmington, DE (US); Meijun Lu, Hockessin, DE (US); Irina Malajovich, Swarthmore, PA (US); Daniela Rodica Radu, Hockessin, DE (US)

(73) Assignee: E I DU PONT DE NEMOURS AND COMPANY, Wilmington, DE (US)

(21) Appl. No.: 13/885,499

(22) PCT Filed: Nov. 20, 2011
(86) PCT No.: PCT/US11/61569

§ 371 Date: May 15, 2013

Related U.S. Application Data
(60) Provisional application No. 61/415,957, filed on Nov. 22, 2010.
(60) Provisional application No. 61/415,965, filed on Nov. 22, 2010.

(51) Int. Cl. H01L 31/0272

(52) U.S. Cl. CPC H01L 31/0272
USPC 136/264; 252/519.4; 252/512

(57) ABSTRACT

This invention provides compositions and the processes for preparing the compositions that are useful for preparing films of CZTS and its selenium analogues on a substrate. Such films are useful in preparing photovoltaic devices. This invention also provides processes for preparing a semiconductor layer comprising CZTS/Se microparticles embedded in an inorganic matrix. This invention also provides processes for making a photovoltaic devices and the photovoltaic devices so produced.

This application claims the benefit of U.S. Provisional Patent Application No. 61/415,957, filed Nov. 22, 2010 and U.S. Provisional Patent Application No. 61/415,965, filed Nov. 22, 2010 which are herein incorporated by reference.

### FIELD OF THE INVENTION

This invention provides compositions and processes useful for preparing films of CZTS and its selenium analogues on a substrate. Such films are useful in preparing photovoltaic devices. This invention also provides a semiconductor layer comprising CZTS/Se microparticles embedded in an inorganic matrix. This invention also provides a photovoltaic device. This invention also encompasses methods of preparing the films, coated substrates and photovoltaic devices disclosed herein.

### BACKGROUND

Thin-film photovoltaic cells typically use semiconductors such as CdTe or copper indium gallium sulfide/selenide (CIGS) as an energy absorber material. Due to the toxicity of cadmium and the limited availability of indium, alternatives are sought. Copper zinc tin sulfide (Cu₂ZnSnS₄ or “CZTS”) possesses a band gap energy of about 1.5 eV and a large absorption coefficient (approx. 10⁴ cm⁻¹), making it a promising CIGS replacement.

The most common approach to fabricating CZTS thin films is to deposit elemental or binary precursors, such as Cu, Zn, Sn, ZnS, and SnS, using a vacuum technique, which is then followed by the chalcogenization of the precursors. The resulting films are continuous deposits which conform to the substrate. However, typical vacuum techniques require complicated equipment and are therefore intrinsically expensive processes.

Low-cost routes to CZTS are available, but have deficiencies. For example, electrochemical deposition to form CZTS is an inexpensive process, but compositional non-uniformity and/or the presence of secondary phases prevents this method from generating high-quality CZTS thin-films. CZTS thin-films can also be made by the spray pyrolysis of a solution containing metal salts, typically CuCl, ZnCl₂, and SnCl₄, using thiourea as the sulfur source. This method tends to yield films of poor morphology, density and grain size. CZTS films formed from oxyhydrate precursors deposited by the sol-gel method also have poor morphology and require an H₂S atmosphere for annealing. Photochemical deposition has also been shown to generate p-type CZTS thin films. However, the composition of the product is not well-controlled, and it is difficult to avoid the formation of impurities such as hydroxides. The synthesis of CZTS films from CZTS nanoparticles, which incorporate high-boiling amines as capping agents, has also been disclosed. The presence of capping agents in the nanoparticle layer can contaminate and lower the density of the annealed CZTS film. A hybrid solution-particle approach to CZTS involving the preparation of a hydrazine-based slurry comprising dissolved Cu—Sn chalcogenides (S or S/Se), Zn-chalcogenide particles, and excess chalcogen has been reported. Hydrazine is a highly reactive and potentially explosive solvent that is described in the Merck Index as a “violent poison.”

Mixtures of milled copper, zinc, and tin particles have been used to form CZTS in a complex, multi-step process. This process involves pressing the particle mixture, heating the pressed particles in a vacuum in a sealed tube to form an alloy, melt-spinning to form an alloy strip, mixing the alloy strip with sulfur powder and ball-milling to form a precursor mixture. This mixture can be coated and then annealed under sulfur vapor to form a film of CZTS.

Hence, there still exists a need for simple, low-cost, scalable materials and processes with a low number of operations that provide high-quality, crystalline CZTS films with tunable composition and morphology. There also exists a need for low-temperature, atmospheric-pressure routes to these materials using solvents and reagents with relatively low toxicity.

### SUMMARY

One aspect of this invention is an ink comprising:

a) a plurality of CZTS/Se microparticles;
b) a plurality of particles selected from the group consisting of: CZTS/Se nanoparticles; elemental Cu-, elemental Zn- or elemental Sn-containing particles; binary or ternary Cu-, Zn- or Sn-containing chalcogenide particles; and mixtures thereof; and
c) a vehicle.

Another aspect of this invention is a coated substrate comprising:

a) a substrate; and
b) at least one layer disposed on the substrate comprising:
i) a plurality of CZTS/Se microparticles;
ii) a plurality of particles selected from the group consisting of: CZTS/Se nanoparticles; elemental Cu-, elemental Zn- or elemental Sn-containing particles; binary or ternary Cu-, Zn- or Sn-containing chalcogenide particles; and mixtures thereof.

Another aspect of this invention is a film comprising:

a) an inorganic matrix; and
b) CZTS/Se microparticles characterized by an average longest dimension of 0.5-200 microns, wherein the microparticles are embedded in the inorganic matrix.

A further aspect of this invention is a photovoltaic cell comprising the film as described above.

An additional aspect of this invention is a process comprising disposing an ink onto a substrate to form a coated substrate, wherein the ink comprises:
i) a plurality of CZTS/Se microparticles;
ii) a plurality of particles selected from the group consisting of: CZTS/Se nanoparticles; elemental Cu-, elemental Zn- or elemental Sn-containing particles; binary or ternary Cu-, Zn- or Sn-containing chalcogenide particles; and mixtures thereof; and
iii) a vehicle.

A further aspect of the invention is a process for preparing a coated substrate comprising:

a) providing an ink comprising:
i) a plurality of CZTS/Se microparticles;
ii) a plurality of particles selected from the group consisting of: CZTS/Se nanoparticles; elemental Cu-, Zn- or Sn-containing particles; binary or ternary Cu-, Zn- or Sn-containing chalcogenide particles; and mixtures thereof; and
iii) a vehicle;
   b) heat processing one or more components of the ink; and
   c) depositing the ink from step b) on a substrate.

Another aspect of this invention is a process for producing a photovoltaic cell.

### DETAILED DESCRIPTION

Herein, the terms “solar cell” and “photovoltaic cell” are synonymous unless specifically defined otherwise. These terms refer to devices that use semiconductors to convert visible and near-visible light energy into usable electrical energy. The terms “band gap energy,” “optical band gap,” and “band gap” are synonymous unless specifically defined otherwise. These terms refer to the energy required to generate electron-hole pairs in a semiconductor material, which in general is the minimum energy needed to excite an electron from the valence band to the conduction band.

A subclass of solar cells are monograin layer (MGL) solar cells, also known as monocrystalline and monoparticle membrane solar cells. The MGL consists of monograin powder crystals embedded into an organic resin. A main technological advantage is that the absorber is fabricated separately from the solar cell, which leads to benefits in both the absorber and cell stages of MGL production. High temperatures are often preferred in adsorber material production, while lower temperatures are often preferred in the cell production. Fabricating the absorber and then embedding it in a matrix allows the possibility of using inexpensive, flexible, low-temperature substrates in the manufacture of inexpensive flexible solar cells.

Herein, an inorganic matrix replaces the organic matrix used in traditional MGL. As defined herein, “inorganic matrix” refers to a matrix comprising inorganic semiconductors, precursors to inorganic semiconductors, inorganic insulators, precursors to inorganic insulators, or mixtures thereof. Materials designated as inorganic matrixes can also contain small amounts of other materials, including dopants such as sodium, and organic materials. Examples of suitable inorganic matrixes include Cu₂ZnSn(S,Se)₄, Cu(In,Ga)(S,Se)₂, SiO₂, and precursors thereof. The inorganic matrix is used in combination with microparticles of chalcogenide semiconductor to build a coated film. In some embodiments, the bulk of the functionality comes from the microparticles, and the inorganic matrix plays a role in layer formation and enhancement of the layer performance. The longest dimension of the microparticles can be greater than the average thickness of the inorganic matrix and, in some instances, can span the coated thickness. The longest dimension of the microparticles can be less than or equivalent to the coated thickness, resulting in a film with completely or partially embedded microparticles. The microparticles and inorganic matrix can comprise different materials or can consist of essentially the same composition or can vary in composition, e.g., the chalcogenide or dopant composition can vary.

Herein, grain size refers to the diameter of a grain of granular material, wherein the diameter is defined as the longest distance between two points on its surface. In contrast, crystallite size is the size of a single crystal inside the grain. A single grain can be composed of several crystals. A useful method for obtaining grain size is electron microscopy. ASTM test methods are available for determining planar grain size, that is, characterizing the two-dimensional grain sections revealed by the sectioning plane. Manual grain size measurements are described in ASTM E 112 (equiaxed grain structures with a single size distribution) and E 1182 (specimens with a bi-modal grain size distribution), while ASTM E 1382 describes how any grain size type or condition can be measured using image analysis methods.

Herein, element groups are represented using CAS notation. As used herein, the term “chalcogen” refers to Group VIA elements, and the terms “metal chalcogenides” or “chalcogenides” refer to materials that comprise metals and Group VIA elements. Suitable Group VIA elements include sulfur, selenium and tellurium. Metal chalcogenides are important candidate materials for photovoltaic applications, since many of these compounds have optical band gap values well within the terrestrial solar spectra.

Herein, the term “binary-metal chalcogenide” refers to a chalcogenide composition comprising one metal. The term “ternary-metal chalcogenide” refers to a chalcogenide composition comprising two metals. The term “quaternary-metal chalcogenide” refers to a chalcogenide composition comprising three metals. The term “multinary-metal chalcogenide” refers to a chalcogenide composition comprising two or more metals, and encompasses ternary and quaternary metal chalcogenide compositions.

Herein, the terms “copper tin sulfide” and “CTS” refer to Cu₂SnS₃. “Copper tin selenide” and “CTSe” refer to Cu₂SnSe₃. “Copper tin sulfide/selenide,” “CTS/Se,” and “CTS—Se” encompass all possible combinations of Cu₂Sn(S,Se)₃, including Cu₂SnS₃, Cu₂SnSe₃, and Cu₂SnSₓSe₃₋ₓ, where 0≦x≦3. The terms “copper tin sulfide,” “copper tin selenide,” “copper tin sulfide/selenide,” “CTS,” “CTSe,” “CTS/Se” and “CTS—Se” further encompass fractional stoichiometries, e.g., Cu_{1.80}Sn_{1.05}S₃. That is, the stoichiometry of the elements can vary from a strictly 2:1:3 molar ratio. Similarly, the terms “Cu₂S/Se,” “CuS/Se,” “Cu₄Sn(S/Se)₄,” “Sn(S/Se)₂,” “SnS/Se,” and “ZnS/Se” encompass fractional stoichiometries and all possible combinations of Cu₂(S_{y}Se_{1-y}), Cu(S_{y}Se_{1-y}), Cu₄Sn(S_{y}Se_{1-y})₄, Sn(S_{y}Se_{1-y})₂, Sn(S_{y}Se_{1-y}), and Zn(S_{y}Se_{1-y}) from 0≦y≦1.

Herein, the terms “copper zinc tin sulfide” and “CZTS” refer to Cu₂ZnSnS₄. “Copper zinc tin selenide” and “CZTSe” refer to Cu₂ZnSnSe₄. “Copper zinc tin sulfide/selenide,” “CZTS/Se,” and “CZTS—Se” encompass all possible combinations of Cu₂ZnSn(S,Se)₄, including Cu₂ZnSnS₄, Cu₂ZnSnSe₄, and Cu₂ZnSnSₓSe₄₋ₓ, where 0≦x≦4. The terms “CZTS,” “CZTSe,” “CZTS/Se,” and “CZTS—Se” further encompass copper zinc tin sulfide/selenide semiconductors with fractional stoichiometries, e.g., Cu_{1.94}Zn_{0.63}Sn_{1.3}S₄. That is, the stoichiometry of the elements can vary from a strictly 2:1:1:4 molar ratio. Materials designated as CZTS/Se can also contain small amounts of other elements such as sodium. In addition, the Cu, Zn and Sn in CZTS/Se can be partially substituted by other metals. That is, Cu can be partially replaced by Ag and/or Au; Zn by Fe, Cd and/or Hg; and Sn by C, Si, Ge and/or Pb.

To date, the highest efficiencies have been measured for copper-poor CZTS/Se solar cells, where by “copper-poor” it is understood that the ratio Cu/(Zn+Sn) is less than 1.0. For high efficiency devices, a molar ratio of zinc to tin greater than one is also desirable.

The term “kesterite” is commonly used to refer to materials belonging to the kesterite family of minerals and is also the common name of the mineral CZTS. As used herein, the term “kesterite” refers to crystalline compounds in either the I4- or I4-2m space groups having the nominal formula Cu₂ZnSn(S,Se)₄. It also refers to “atypical kesterites,” wherein zinc has replaced a fraction of the copper, or copper has replaced a fraction of the zinc, to give Cu_{c}Zn_{z}Sn(S,Se)₄, wherein c is greater than two and z is less than one, or c is less than two and z is greater than one. The term “kesterite structure” refers to the structure of these compounds. As used herein, “coherent domain size” refers to the size of crystalline domains over which a defect-free, coherent structure can exist. The coherency comes from the fact that the three-dimensional ordering is not broken inside of these domains. When the coherent grain size is less than about 100 nm in size, appreciable broadening of the x-ray diffraction lines will occur. The domain size can be estimated by measuring the full width at half maximum intensity of the diffraction peak.

Herein the terms “nanoparticle,” “nanocrystal,” and “nanocrystalline particle” are synonymous unless specifically defined otherwise, and are meant to include nanoparticles with a variety of shapes that are characterized by an average longest dimension of about 1 nm to about 500 nm. Herein, by nanoparticle “size” or “size range” or “size distribution,” we mean that the average longest dimension of a plurality of nanoparticles falls within the range. “Longest dimension” is defined herein as the measurement of a nanoparticle from end to end. The “longest dimension” of a particle will depend on the shape of the particle. For example, for particles that are roughly or substantially spherical, the longest dimension will be a diameter of the particle. For other particles, the longest dimension can be a diagonal or a side.

Herein the terms “microparticle”, “microcrystal,” and “microcrystalline particle” are synonymous unless specifically defined otherwise and are meant to include microparticles with a variety of shapes that are characterized by an average longest dimension of at least about 0.5 to about 10 microns. Herein, microparticle “size” or “size range” or “size distribution” are defined the same as described above for nanoparticles.

As defined herein, “coated particles” refers to particles that have a surface coating of organic or inorganic material. Methods for surface-coating inorganic particles are well-known in the art. As defined herein, the terms “surface coating” and “capping agent” are used synonymously and refer to a strongly absorbed or chemically bonded monolayer of organic or inorganic molecules on the surface of the particle(s). In addition to carbon and hydrogen, the organic capping agents can comprise functional groups, including nitrogen-, oxygen-, sulfur-, selenium-, and phosphorus-based functional groups. Suitable inorganic capping agents can comprise chalcogenides, including metal chalcogenides, and zintl ions, wherein zintl ions refers to homopolyatomic anions and heteropolyatomic anions that have intermetallic bonds between the same or different metals of the main group, transition metals, lanthanides, and/or actinides.

Elemental and metal chalcogenide particles can be composed only of the specified elements or can be doped with small amounts of other elements. As used herein, the term “alloy” refers to a substance that is a mixture, as by fusion, of two or more metals. Throughout the specification, all reference to wt % of particles is meant to include the surface coating. Many suppliers of nanoparticles use undisclosed or proprietary surface coatings that act as dispersing aids. Throughout the specification, all reference to wt % of particles is meant to include the undisclosed or proprietary coatings that the manufacturer may, or may not, add as a dispersant aid. For instance, a commercial copper nanopowder is considered nominally 100 wt % copper.

Herein, by “O-, N-, S-, and Se-based functional groups” is meant univalent groups other than hydrocarbyl and substituted hydrocarbyl that comprise O-, N-, S-, or Se-heteroatoms, wherein the free valence is located on this heteroatom. Examples of O-, N-, S-, and Se-based functional groups include alkoxides, amidos, thiolates, and selenolates.

Herein, the term “metal salts” refers to compositions wherein metal cations and inorganic anions are joined by ionic bonding. Relevant classes of inorganic anions comprise oxides, sulfides, selenides, carbonates, sulfates and halides.

As defined herein, a “hydrocarbyl group” is a univalent group containing only carbon and hydrogen. Examples of hydrocarbyl groups include unsubstituted alkyls, cycloalkyls, and aryl groups, including alkyl-substituted aryl groups. Suitable hydrocarbyl groups and alkyl groups contain 1 to about 30 carbons, or 1 to 25, 1 to 20, 1 to 15, 1 to 10, 1 to 5, 1 to 4, or 1 to 2 carbons. By “heteroatom-substituted hydrocarbyl” is meant a hydrocarbyl group that contains one or more heteroatoms wherein the free valence is located on carbon, not on the heteroatom. Examples include hydroxyethyl and carbomethoxyethyl. Suitable heteroatom substituents include O-, N-, S-, Se-, halogen-, and tri(hydrocarbyl)silyl. In a substituted hydrocarbyl, all of the hydrogens can be substituted, as in trifluoromethyl. Herein, the term “tri(hydrocarbyl)silyl” encompasses silyl substituents, wherein the substituents on silicon are hydrocarbyls.

### Inks

One aspect of this invention is an ink comprising:

a) a plurality of CZTS/Se microparticles;
b) a plurality of particles selected from the group consisting of: CZTS/Se nanoparticles; elemental Cu-, elemental Zn- or elemental Sn-containing particles; binary or ternary Cu-, Zn- or Sn-containing chalcogenide particles; and mixtures thereof; and
c) a vehicle.

This ink is referred to as a CZTS/Se precursor ink, as it contains the precursors for forming a CZTS/Se thin film. In some embodiments, the ink consists essentially of components (a)-(c).

Chalcogen Sources.

In some embodiments, the ink comprises the CZTS/Se nanoparticles. In some embodiments, the ink comprises Cu-, Zn-, or Sn-containing chalcogenide particles selected from the group consisting of: sulfide particles, selenide particles, sulfide/selenide particles, and mixtures thereof. In some embodiments, the ink further comprises an elemental chalcogen selected from the group consisting of: sulfur, selenium, and mixtures thereof.

Molar Ratios of the Ink.

In some embodiments, the molar ratio of Cu:Zn:Sn is about 2:1:1. In some embodiments, the molar ratio of Cu to (Zn+Sn) is less than one. In some embodiments, the molar ratio of Zn to Sn is greater than one. These embodiments are encompassed by the term “a molar ratio of Cu:Zn:Sn is about 2:1:1,” which covers a range of compositions such as Cu:Zn:Sn ratios of 1.75:1:1.35 and 1.78:1:1.26. In some embodiments, the amount of Cu, Zn, and Sn can deviate from a 2:1:1 molar ratio by +/−40 mole %, +/−30 mole %, +/−20 mole %, +/−10 mole %, or +/−5 mole %.

In some embodiments, the molar ratio of total chalcogen to (Cu+Zn+Sn) is at least about 1. As defined herein, the moles of total chalcogen are determined by multiplying the moles of each chalcogen-containing species by the number of equivalents of chalcogen that it comprises and then summing these quantities. The moles of (Cu+Zn+Sn) are determined by multiplying the moles of each Cu-, or Zn- or Sn-containing species by the number of equivalents of Cu or Zn or Sn that it comprises and then summing these quantities. As defined herein, sources for the total chalcogen include CZTS/Se microparticles and nanoparticles, chalcogenide particles and elemental chalcogen ink components. As an example, the molar ratio of total chalcogen to (Cu+Zn+Sn) for an ink comprising Cu₂ZnSnS₄ microparticles, Cu₂S particles, Zn particles, SnS₂ particles and sulfur=[4(moles Cu₂ZnSnS₄)+(moles of Cu₂S)+2(moles of SnS₂)+(moles of S)]/[4(moles Cu₂ZnSnS₄)+2(moles of Cu₂S)+(moles of Zn)+(moles of SnS₂)].

Particle Sizes.

The particles can be purchased or synthesized by known techniques such milling and sieving of bulk quantities of the material. In some embodiments, the particles have an average longest dimension of less than about 5 microns, 4 microns, 3 microns, 2 microns, 1.5 microns, 1.25 microns, 1.0 micron, or 0.75 micron.

Microparticles.

The microparticles can have an average longest dimension of at least about 0.5, 0.6, 0.7, 0.8, 0.9, 1.0, 1.1, 1.2, 1.3, 1.4, 1.5, 1.6, 1.7, 1.8, 1.9, 2.0, 3.0, 4.0, 5.0, 7.5, 10, 15, 20, 25, 50, 75, 100, 125, 150, 175, or 200 microns.

In embodiments in which in which the average longest dimension of the microparticles is less than the average thickness of the coated and/or annealed absorber layer, useful size ranges for microparticles are at least about 0.5 to about 10 microns, 0.6 to 5 microns, 0.6 to 3 microns, 0.6 to 2 microns, 0.6 to 1.5 microns, 0.6 to 1.2 microns, 0.8 to 2 microns, 1.0 to 3.0 microns, 1.0 to 2.0 microns, or 0.8 to 1.5 microns. In embodiments in which the average longest dimension of the microparticles is longer than the average thickness of the coated and/or annealed absorber layer, useful size ranges for microparticles are at least about 1 to about 200 microns, 2 to 200 microns, 2 to 100 microns, 3 to 100 microns, 2 to 50 microns, 2 to 25 microns, 2 to 20 microns, 2 to 15 microns, 2 to 10 microns, 2 to 5 microns, 4 to 50 microns, 4 to 25 microns, 4 to 20 microns, 4 to 15 microns, 4 to 10 microns, 6 to 50 microns, 6 to 25 microns, 6 to 20 microns, 6 to 15 microns, 6 to 10 microns, 10 to 50 microns, 10 to 25 microns, or 10 to 20 microns. The average thickness of the coated and/or annealed absorber layer can be determined by profilometry. The average longest dimension of the microparticles can be determined by electron microscopy.

Nanoparticles.

In some embodiments, the particles comprise nanoparticles. The nanoparticles can have an average longest dimension of less than about 500 nm, 400 nm, 300 nm, 250 nm, 200 nm, 150 nm, or 100 nm, as determined by electron microscopy. The nanoparticles can be purchased or synthesized by known techniques, such as: decomposition and reduction of metal salts and complexes; chemical vapor deposition; electrochemical deposition; use of gamma-, x-ray, laser or UV-irradiation; ultrasonic or microwave treatment; electron- or ion-beams; arc discharge; electric explosion of wires; or biosynthesis.

Capping Agent.

In some embodiments, the particles further comprise a capping agent. The capping agent can aid in the dispersion of particles and can also inhibit their interaction and agglomeration in the ink. Suitable capping agents include:

(a) Organic molecules that contain functional groups such as N-, O-, S-, Se- or P-based functional groups;

(b) Lewis bases;

(c) Amines, thiols, selenols, phosphine oxides, phosphines, phosphinic acids, pyrrolidones, pyridines, carboxylates, phosphates, heteroaromatics, peptides, and alcohols;

(d) Alkyl amines, alkyl thiols, alkyl selenols, trialkylphosphine oxide, trialkylphosphines, alkylphosphonic acids, polyvinylpyrrolidone, polycarboxylates, polyphosphates, polyamines, pyridine, alkylpyridines, aminopyridines, peptides comprising cysteine and/or histidine residues, ethanolamines, citrates, thioglycolic acid, oleic acid, and polyethylene glycol;

(e) Inorganic chalcogenides, including metal chalcogenides, and zintl ions;

(f) Se²⁻, Se₂²⁻, Se₃²⁻, Se₄²⁻, Se₆²⁻, Te₂²⁻, Te₃²⁻, Te₄²⁻, Sn₄²⁻, Sn₅²⁻, Sn₉³⁻, Sn₉⁴⁻, SnSe₄⁴⁻, SnTe₄⁴⁻, Sn₂S₆⁴⁻, Sn₂Te₆⁴⁻, wherein the positively charged counterions can be alkali metal ions, ammonium, hydrazinium, or tetraalkylammonium;

(g) Degradable capping agents, including dichalcogenocarbamates, monochalcogenocarbamates, xanthates, trithiocarbonates, dichalcogenoimidodiphosphates, thiobiurets, dithiobiurets, chalcogenosemicarbazides, and tetrazoles. These capping agents can be degraded by thermal and/or chemical processes, such as acid- and base-catalyzed processes. Degradable capping agents include: dialkyl dithiocarbamates, dialkyl monothiocarbamates, dialkyl diselenocarbamates, dialkyl monoselenocarbamates, alkyl xanthates, alkyl trithiocarbonates, disulfidoimidodiphosphates, diselenoimidodiphosphates, tetraalkyl thiobiurets, tetraalkyl dithiobiurets, thiosemicarbazides, selenosemicarbazides, tetrazole, alkyl tetrazoles, amino-tetrazoles, thio-tetrazoles, and carboxylated tetrazoles. In some embodiments, Lewis bases (e.g., amines) can be added to nanoparticles stabilized by carbamate, xanthate, and trithiocarbonate capping agents to catalyze their removal from the nanoparticle;

(h) Molecular precursor complexes to copper chalcogenides, zinc chalcogenides, and tin chalcogenides. Ligands for these molecular precursor complexes include: thio groups, seleno groups, thiolates, selenolates, and thermally degradable ligands, as described above. Thiolates and selenolates include: alkyl thiolates, alkyl selenolates, aryl thiolates, and aryl selenolates;

(i) Molecular precursor complexes to CuS/Se, Cu₂S/Se, ZnS/Se, SnS/Se, Sn(S/Se)₂, Cu₂Sn(S/Se)₃, Cu₂ZnSn(S/Se)₄;

(j) The solvent in which the particle is formed, such as oleylamine; and

(k) Short-chain carboxylic acids, such as formic, acetic, or oxalic acids.

The Lewis base can be chosen such that it has a boiling temperature at ambient pressure that is greater than or equal to about 200° C., 150° C., 120° C., or 100° C., and/or can be selected from the group consisting of: organic amines, phosphine oxides, phosphines, thiols, and mixtures thereof. In some embodiments, the capping agent comprises a surfactant or a dispersant.

Volatile Capping Agents.

In some embodiments, the particles comprise a volatile capping agent. A capping agent is considered volatile if, instead of decomposing and introducing impurities when a composition or ink of nanoparticles is formed into a film, it evaporates during film deposition, drying or annealing. Volatile capping agents include those having a boiling point less than about 200° C., 150° C., 120° C., or 100° C. at ambient pressure. Volatile capping agents can be adsorbed or bonded onto particles during synthesis or during an exchange reaction. Thus, in one embodiment, particles, or an ink or reaction mixture of particles stabilized by a first capping agent, as incorporated during synthesis, are mixed with a second capping agent that has greater volatility to exchange in the particles the second capping agent for the first capping agent. Suitable volatile capping agents include: ammonia, methyl amine, ethyl amine, butylamine, tetramethylethylene diamine, acetonitrile, ethyl acetate, butanol, pyridine, ethanethiol, propanethiol, butanethiol, t-butylthiol, pentanethiol, hexanethiol, tetrahydrofuran, and diethyl ether. Suitable volatile capping agents can also include: amines, amidos, amides, nitriles, isonitriles, cyanates, isocyanates, thiocyanates, isothiocyanates, azides, thiocarbonyls, thiols, thiolates, sulfides, sulfinates, sulfonates, phosphates, phosphines, phosphites, hydroxyls, hydroxides, alcohols, alcoholates, phenols, phenolates, ethers, carbonyls, carboxylates, carboxylic acids, carboxylic acid anhydrides, glycidyls, and mixtures thereof.

### CZTS/Se Microparticles.

The ink comprises CZTS/Se microparticles. The CZTS/Se microparticles can be synthesized by methods known in the art, such as by heating a mixture of Cu, Zn and Sn sulfides together in a furnace at high temperatures. A particularly useful method for the synthesis of CZTS/Se microparticles involves reacting ground Cu-, Zn- and Sn-containing binary and/or ternary chalcogenides together in a molten flux in an isothermal recrystallization process. The crystal size of the materials can be controlled by the temperature and duration of the recrystallization process and by the chemical nature of the flux. A particularly useful aqueous method for synthesizing CZTS/Se microparticles is described below. In some instances, the microparticles synthesized via these methods might be larger than desired. In such cases, the CZTS/Se microparticles can be milled or sieved using standard techniques to achieve the desired particle size.

In some instances, the CZTS/Se microparticles comprise a capping agent. The coated CZTS/Se microparticles can be synthesized by standard techniques known in the art, such as mixing the microparticle with a liquid capping agent, optionally with heating, and then washing the coated particles to remove excess capping agent. CZTS/Se microparticles capped with CZTS/Se molecular precursors can be synthesized by mixing CZTS/Se microparticles with a CZTS/Se molecular precursor ink comprising:

a) a copper source selected from the group consisting of copper complexes of N-, O-, C-, S-, and Se-based organic ligands, copper sulfides, copper selenides, and mixtures thereof;
b) a tin source selected from the group consisting of tin complexes of N-, O-, C-, S-, and Se-based organic ligands, tin hydrides, tin sulfides, tin selenides, and mixtures thereof; and
c) a zinc source selected from the group consisting of zinc complexes of N-, O-, C-, S-, and Se-based organic ligands, zinc sulfides, zinc selenides, and mixtures thereof.

In some embodiments, the molecular precursor ink further comprises a chalcogen compound. Suitable chalcogen compounds include: elemental S, elemental Se, CS₂, CSe₂, CSSe, R¹S—Z, R¹Se—Z, R¹⁵—SR¹, R¹Se—SeR¹, R²C(S)S—Z, R²C(Se)Se—Z, R²C(Se)S—Z, R¹C(O)S—Z, R¹C(O)Se—Z, and mixtures thereof, with each Z independently selected from the group consisting of: H, NR⁴₄, and SiR⁵₃; wherein each R¹ and R⁵ is independently selected from the group consisting of: hydrocarbyl and O-, N-, S-, Se-, halogen- and tri(hydrocarbyl)silyl-substituted hydrocarbyl; each R² is independently selected from the group consisting of hydrocarbyl, O-, N-, S-, Se-, halogen-, and tri(hydrocarbyl)silyl-substituted hydrocarbyl, and O-, N-, S-, and Se-based functional groups; and each R⁴ is independently selected from the group consisting of hydrogen, O-, N-, S-, Se-, halogen- and tri(hydrocarbyl)silyl-substituted hydrocarbyl, and O-, N-, S-, and Se-based functional groups. In some embodiments, elemental sulfur, elemental selenium, or a mixture of elemental sulfur and selenium is present. In some embodiments, the molecular precursor ink further comprises a vehicle. Suitable vehicles include solvents. In some embodiments, the mixture of CZTS/Se molecular precursors and microparticles is heat-processed at a temperature of greater than about 50° C., 75° C., 90° C., 100° C., 110° C., 120° C., 130° C., 140° C., 150 C.°, 160° C., 170° C., 180° C. or 190° C. Suitable heating methods include conventional heating and microwave heating. In some embodiments, the CZTS/Se microparticles are mixed with a molecular precursor ink wherein solvent(s) comprises less than about 90 wt %, 80 wt %, 70 wt %, 60 wt %, or 50 wt % of the ink, based upon the total weight of the ink. Following mixing and optional heating, the CZTS/Se microparticles are washed with solvent to remove excess molecular precursor.

### Plurality of Particles.

Molar Ratios of the Plurality of Particles.

In some embodiments, the molar ratio of Cu:Zn:Sn is about 2:1:1 in the plurality of particles. In some embodiments, the molar ratio of Cu to (Zn+Sn) is less than one in the plurality of particles. In some embodiments, the molar ratio of Zn to Sn is greater than one in the plurality of particles. In some embodiments, the amount of Cu, Zn, and Sn can deviate from a 2:1:1 molar ratio by +/−40 mole %, +/−30 mole %, +/−20 mole %, +/−10 mole %, or +/−5 mole %.

In some embodiments, the molar ratio of total chalcogen to (Cu+Zn+Sn) is at least about 1 in the plurality of particles, and is determined as defined above for the ink.

Elemental Particles.

In some embodiments, the plurality of particles comprises elemental Cu-, Zn- or Sn-containing particles. In some embodiments, the plurality of particles consists essentially of elemental Cu-, Zn- or Sn-containing particles. Suitable elemental Cu-containing particles include: Cu particles, Cu—Sn alloy particles, Cu—Zn alloy particles, and mixtures thereof. Suitable elemental Zn-containing particles include: Zn particles, Cu—Zn alloy particles, Zn—Sn alloy particles, and mixtures thereof. Suitable elemental Sn-containing particles include: Sn particles, Cu—Sn alloy particles, Zn—Sn alloy particles, and mixtures thereof. In some embodiments, the elemental Cu-, Zn- or Sn-containing particles are nanoparticles. The elemental Cu-, Zn- or Sn-containing nanoparticles can be obtained from Sigma-Aldrich (St. Louis, Mo.), Nanostructured and Amorphous Materials, Inc. (Houston, Tex.), American Elements (Los Angeles, Calif.), Inframat Advanced Materials LLC (Manchester, Conn.), Xuzhou Jiechuang New Material Technology Co., Ltd. (Guangdong, China), Absolute Co. Ltd. (Volgograd, Russian Federation), MTI Corporation (Richmond, Va.), or Reade Advanced Materials (Providence, R.I.). Elemental Cu-, Zn- or Sn-containing nanoparticles can also be synthesized according to known techniques, as described above. In some instances, the elemental Cu-, Zn- or Sn-containing particles comprise a capping agent.

Binary or Ternary Chalcogenide Particles.

In some embodiments, the plurality of particles comprises binary or ternary Cu-, Zn- or Sn-containing chalcogenide particles. In some embodiments, the plurality of particles consists essentially of binary or ternary Cu-, Zn- or Sn-containing chalcogenide particles; and mixtures thereof. In some embodiments, the chalcogenide is a sulfide or selenide. Suitable Cu-containing binary or ternary chalcogenide particles include: Cu₂S/Se particles, CuS/Se particles, Cu₂Sn(S/Se)₃ particles, Cu₄Sn(S/Se)₄ particles, and mixtures thereof. Suitable Zn-containing binary chalcogenide particles include ZnS/Se particles. Suitable Sn-containing binary or ternary chalcogenide particles include: Sn(S/Se)₂ particles, SnS/Se particles, Cu₂Sn(S/Se)₃ particles, Cu₄Sn(S/Se)₄ particles, and mixtures thereof. In some instances, the binary or ternary Cu-, Zn- or Sn-containing chalcogenide nanoparticles comprise a capping agent. In some embodiments, the binary or ternary Cu-, Zn- or Sn-containing chalcogenide nanoparticles can be purchased from Reade Advanced Materials (Providence, R.I.) or synthesized according to known techniques. A particularly useful aqueous method for synthesizing mixtures of copper-, zinc- and tin-containing chalcogenide nanoparticles follows:
(a) providing a first aqueous solution comprising two or more metal salts and one or more ligands;
(b) optionally, adding a pH-modifying substance to form a second aqueous solution;
(c) combining the first or second aqueous solution with a chalcogen source to provide a reaction mixture; and
(d) agitating and optionally heating the reaction mixture to produce metal chalcogenide nanoparticles.

In one embodiment, the process further comprises separating the metal chalcogenide nanoparticles from the reaction mixture. In another embodiment, the process further comprises cleaning the surface of the nanoparticles. In another embodiment, the process further comprises reacting the surface of the nanoparticles with capping groups.

CZTS/Se Nanoparticles.

In some embodiments, the plurality of particles comprises CZTS/Se nanoparticles. In some embodiments, the plurality of particles consists essentially of CZTS/Se nanoparticles. In some embodiments, the CZTS/Se nanoparticles comprise a capping agent. The CZTS/Se nanoparticles can be synthesized by methods known in the art, as described above. A particularly useful aqueous method for synthesizing CZTS/Se nanoparticles comprises steps (a)-(d) as described above in the aqueous method for synthesizing mixtures of copper-, zinc- and tin-containing chalcogenide nanoparticles, followed by steps (e) and (f):
(e) separating the metal chalcogenide nanoparticles from reaction by-products; and
(f) heating the metal chalcogenide nanoparticles to provide crystalline multinary-metal chalcogenide particles.

The annealing time can be used to control the CZTS/Se particle size, with particles ranging from nanoparticles to microparticles, as annealing time lengthens.

Capped Nanoparticles.

In some instances, the nanoparticles comprise a capping agent. Coated binary, ternary, and quaternary chalcogenide nanoparticles, including CuS, CuSe, ZnS, ZnSe, SnS, Cu₂SnS₃, and Cu₂ZnSnS₄, can be prepared from corresponding metal salts or complexes by reaction of the metal salt or complex with a source of sulfide or selenide in the presence of one or more stabilizing agents at a temperature between 0° C. and 500° C., or between 150° C. and 350° C. In some circumstances, the stabilizing agent also provides the coating. The chalcogenide nanoparticles can be isolated, for example, by precipitation by a non-solvent followed by centrifugation, and can be further purified by washing, or dissolving and re-precipitating. Suitable metal salts and complexes for this synthetic route include Cu(I), Cu(II), Zn(II), Sn(II) and Sn(IV) halides, acetates, nitrates, and 2,4-pentanedionates. Suitable chalcogen sources include elemental sulfur, elemental selenium, Na₂S, Na₂Se, (NH₄)₂S, (NH₄)₂Se, thiourea, and thioacetamide. Suitable stabilizing agents include the capping agents disclosed above. In particular, suitable stabilizing agents include: dodecylamine, tetradecyl amine, hexadecyl amine, octadecyl amine, oleylamine, trioctyl amine, trioctylphosphine oxide, other trialkylphosphine oxides, and trialkylphosphines.

Cu₂S nanoparticles can be synthesized by a solvothermal process, in which the metal salt is dissolved in deionized water. A long-chain alkyl thiol or selenol (e.g., 1-dodecanethiol or 1-dodecaneselenol) can serve as both the sulfur source and a dispersant for nanoparticles. Some additional ligands, including acetate and chloride, can be added in the form of an acid or a salt. The reaction is typically conducted at a temperature between 150° C. and 300° C. and at a pressure between 150 psig to 250 psig nitrogen. After cooling, the product can be isolated from the non-aqueous phase, for example, by precipitation using a non-solvent and filtration.

The chalcogenide nanoparticles can also be synthesized by an alternative solvothermal process in which the corresponding metal salt is dispersed along with thioacetamide, thiourea, selenoacetamide, selenourea or other source of sulfide or selenide ions and an organic stabilizing agent (e.g., a long-chain alkyl thiol or a long-chain alkyl amine) in a suitable solvent at a temperature between 150° C. and 300° C. The reaction is typically conducted at a pressure between 150 psig nitrogen and 250 psig nitrogen. Suitable metal salts for this synthetic route include Cu(I), Cu(II), Zn(II), Sn(II) and Sn(IV) halides, acetates, nitrates, and 2,4-pentanedionates.

The resultant chalcogenide nanoparticles obtained from any of the three routes are coated with the organic stabilizing agent(s), as can be determined by secondary ion mass spectrometry and nuclear magnetic resonance spectroscopy. The structure of the inorganic crystalline core of the coated nanoparticles obtained can be determined by X-ray diffraction (XRD) and transmission electron microscopy (TEM) techniques.

Vehicle.

The ink comprises a vehicle to carry the particles. The vehicle is typically a fluid or a low-melting solid with a melting point of less than about 100° C., 90° C., 80° C., 70° C., 60° C., 50° C., 40° C., or 30° C. In some embodiments, the vehicle comprises solvents. Suitable solvents include: aromatics, heteroaromatics, alkanes, chlorinated alkanes, ketones, esters, nitriles, amides, amines, thiols, selenols, pyrrolidinones, ethers, thioethers, selenoethers, alcohols, water, and mixtures thereof. Useful examples of these solvents include toluene, p-xylene, mesitylene, benzene, chlorobenzene, dichlobenzene, trichlorobenzene, pyridine, 2-aminopyridine, 3-aminopyridine, 2,2,4-trimethylpentane, n-octane, n-hexane, n-heptane, n-pentane, cyclohexane, chloroform, dichloromethane, 1,1,1-trichloroethane, 1,1,2-trichloroethane, 1,1,2,2-tetrachloroethane, 2-butanone, acetone, acetophenone, ethyl acetate, acetonitrile, benzonitrile, N,N-dimethylformamide, butylamine, hexylamine, octylamine, 3-methoxypropylamine, 2-methylbutylamine, isoamylamine, 1-propanethiol, 1-butanethiol, 2-butanethiol, 2-methyl-1-propanethiol, t-butyl thiol, 1-pentanethiol, 3-methyl-1-butanethiol, cyclopentanethiol, 1-hexanethiol, cyclohexanethiol, 1-heptanethiol, 1-octanethiol, 2-ethyhexanethiol, 1-nonanethiol, tert-nonyl mercaptan, 1-decanethiol, mercaptoethanol, 4-cyano-1-butanethiol, butyl 3-mercaptoproprionate, methyl 3-mercaptoproprionate, 1-mercapto-2-propanol, 3-mercapto-1-propanol, 4-mercapto-1-butanol, 6-mercapto-1-hexanol, 2-phenylethanethiol, thiophenol, N-methyl-2-pyrrolidinone, tetrahydrofuran, 2,5-dimethylfuran, diethyl ether, ethylene glycol diethyl ether, diethylsulfide, diethylselenide, 2-methoxyethanol, isopropanol, butanol, ethanol, methanol and mixtures thereof. In some embodiments, the wt % of the vehicle in the ink is about 98 to about 5 wt %, 90 to 10 wt %, 80 to 20 wt %, 70 to 30 wt %, or 60 to 40 wt %, 98 to 50 wt %, 98 to 60 wt %, 98 to 70 wt %, 98 to 75 wt %, 98 to 80 wt %, 98 to 85 wt %, 95 to 75 wt %, 95 to 80 wt %, or 95 to 85 wt % based upon the total weight of the ink. In some embodiments, the vehicle can function as a dispersant or capping agent, as well as being the carrier vehicle for the particles. Solvent-based vehicles that are particularly useful as capping agents comprise heteroaromatics, amines, thiols, selenols, thioethers, and selenoethers.

### Additional Ink Components

In addition to the CZTS/Se microparticles and the plurality of particles, in various embodiments the ink can further comprise additives, an elemental chalcogen, or mixtures thereof.

Additives.

In some embodiments, the ink further comprises one or more additives. Suitable additives include dispersants, surfactants, polymers, binders, ligands, capping agents, defoamers, dispersants, surfactants, polymers, binders, ligands, capping agents, defoamers, thickening agents, corrosion inhibitors, plasticizers, thixotropic agents, viscosity modifiers, and dopants. In some embodiments, additives are selected from the group consisting of: capping agents, dopants, polymers, and surfactants. In some embodiments, the ink comprises up to about 10 wt %, 7.5 wt %, 5 wt %, 2.5 wt % or 1 wt % additives, based upon the total weight of the ink. Suitable capping agents comprise the capping agents, including volatile capping agents, described above.

Dopants.

Suitable dopants include sodium and alkali-containing compounds selected from the group consisting of: alkali compounds comprising N-, O-, C-, S-, or Se-based organic ligands, alkali sulfides, alkali selenides, and mixtures thereof. In other embodiments, the dopant comprises an alkali-containing compound selected from the group consisting of: alkali-compounds comprising amidos; alkoxides; acetylacetonates; carboxylates; hydrocarbyls; O-, N-, S-, Se-, halogen-, and tri(hydrocarbyl)silyl-substituted hydrocarbyls; thio- and selenolates; thio-, seleno-, and dithiocarboxylates; dithio-, diseleno-, and thioselenocarbamates; and dithioxanthogenates. Other suitable dopants include antimony chalcogenides selected from the group consisting of: antimony sulfide and antimony selenide.

Polymers and Surfactants.

Suitable polymeric additives include vinylpyrrolidone-vinylacetate copolymers and (meth)acrylate copolymers, including PVP/VA E-535 (International Specialty Products) and Elvacite® 2028 binder and Elvacite® 2008 binder (Lucite International, Inc.). In some embodiments, polymers can function as binders or dispersants.

Suitable surfactants comprise siloxy-, fluoryl-, alkyl-, alkynyl-, and ammonium-substituted surfactants. These include, for example, Byk® surfactants (Byk Chemie), Zonyl® surfactants (DuPont), Triton® surfactants (Dow), Surfynol® surfactants (Air Products), Dynol® surfactants (Air Products), and Tego® surfactants (Evonik Industries AG). In certain embodiments, surfactants can function as coating aids, capping agents, or dispersants.

In some embodiments, the ink comprises one or more binders or surfactants selected from the group consisting of: decomposable binders; decomposable surfactants; cleavable surfactants; surfactants with a boiling point less than about 250° C.; and mixtures thereof. Suitable decomposable binders include: homo- and co-polymers of polyethers; homo- and co-polymers of polylactides; homo- and co-polymers of polycarbonates; homo- and co-polymers of poly[3-hydroxybutyric acid]; homo- and co-polymers of polymethacrylates; and mixtures thereof. A suitable low boiling surfactant is Surfynol® 61 surfactant from Air Products. Cleavable surfactants useful herein as capping agents include Diels-Alder adducts, thiirane oxides, sulfones, acetals, ketals, carbonates, and ortho esters. Cleavable surfactants include: alkyl-substituted Diels Alder adducts, Diels Alder adducts of furans; thiirane oxide; alkyl thiirane oxides; aryl thiirane oxides; piperylene sulfone, butadiene sulfone, isoprene sulfone, 2,5-dihydro-3-thiophene carboxylic acid-1,1-dioxide-alkyl esters, alkyl acetals, alkyl ketals, alkyl 1,3-dioxolanes, alkyl 1,3-dioxanes, hydroxyl acetals, alkyl glucosides, ether acetals, polyoxyethylene acetals, alkyl carbonates, ether carbonates, polyoxyethylene carbonates, ortho esters of formates, alkyl ortho esters, ether ortho esters, and polyoxyethylene ortho esters.

Elemental Chalcogen.

In some embodiments, the ink comprises an elemental chalcogen selected from the group consisting of sulfur, selenium, and mixtures thereof. Useful forms of sulfur and selenium include powders that can be obtained from Sigma-Aldrich (St. Louis, Mo.) and Alfa Aesar (Ward Hill, Mass.). In some embodiments, the chalcogen powder is soluble in the ink vehicle. If the chalcogen is not soluble in the vehicle, its particle size can be 1 nm to 200 microns. In some embodiments, the particles have an average longest dimension of less than about 100 microns, 50 microns, 25 microns, 10 microns, 5 microns, 4 microns, 3 microns, 2 microns, 1.5 microns, 1.25 microns, 1.0 micron, 0.75 micron, 0.5 micron, 0.25 micron, or 0.1 micron. In some embodiments, the chalcogen particles are smaller than the thickness of the film that is to be formed. The chalcogen particles can be formed by ball milling, evaporation-condensation, melting and spraying (“atomization”) to form droplets, or emulsification to form colloids.

Ink Preparation.

Preparing the ink typically comprises mixing the components by any conventional method. In some embodiments, the preparation is conducted under an inert atmosphere. In some embodiments, the wt % of the microparticles, based upon the total weight of the microparticles and plurality of particles, ranges from about 95 to about 5 wt %. In some embodiments, the wt % of the microparticles, based upon the weight of the microparticles and the plurality of particles, is less than about 90 wt %, 80 wt %, 70 wt %, 60 wt %, 50 wt %, 40 wt %, 30 wt %, 20 wt %, 10 wt %, or 5 wt %.

In some embodiments, particularly those in which the average longest dimension of the microparticles is longer than the desired average thickness of the coated and/or annealed absorber layer, the ink is prepared on a substrate. Suitable substrates for this purpose are as described below. For example, the plurality of particles can be deposited on the substrate, with suitable deposition techniques as described below. Then the CZTS/Se microparticles can be added to the plurality of particles by techniques such as sprinkling the microparticles onto the deposited plurality of particles.

Heat-Processing of the Ink.

In some embodiments, the ink is heat-processed at a temperature of greater than about 100° C., 110° C., 120° C., 130° C., 140° C., 150 C.°, 160° C., 170° C., 180° C., or 190° C. before coating on the substrate. In some embodiments, just the plurality of particles and the vehicle are heat-processed prior to the addition of the microparticles. Suitable heating methods include conventional heating and microwave heating. This heat-processing step can aid the dispersion and reaction of the particles. Films made from heat-processed inks can have smooth surfaces, an even distribution of particles within the film as observed by SEM, and improved performance in photovoltaic devices as compared to inks of the same composition that were not heat-processed. This optional heat-processing step is often carried out under an inert atmosphere.

Mixtures of Inks.

In some embodiments two or more inks are prepared separately, with each ink comprising CZTS/Se microparticles and a plurality of particles. The two or more inks can then be combined following mixing or following heat-processing. This method is especially useful for controlling stoichiometry and obtaining CZTS/Se of high purity, as prior to mixing, separate films from each ink can be coated, annealed, and analyzed by XRD. The XRD results can guide the selection of the type and amount of each ink to be combined. For example, an ink yielding an annealed film of CZTS/Se with traces of copper sulfide and zinc sulfide can be combined with an ink yielding an annealed film of CZTS/Se with traces of tin sulfide, to form an ink that yields an annealed film comprising only CZTS/Se, as determined by XRD. In other embodiments, an ink comprising a complete set of reagents is combined with ink(s) comprising a partial set of reagents. As an example, an ink containing only a tin source can be added in varying amounts to an ink comprising a complete set of reagents, and the stoichiometry can be optimized based upon the resulting device performances of annealed films of the mixtures.

### Coated Substrate

Another aspect of this invention is a process comprising disposing an ink onto a substrate to form a coated substrate, wherein the ink comprises:
i) a plurality of CZTS/Se microparticles;
ii) a plurality of particles selected from the group consisting of: CZTS/Se nanoparticles; elemental Cu-, elemental Zn- or elemental Sn-containing particles; binary or ternary Cu-, Zn- or Sn-containing chalcogenide particles; and mixtures thereof; and
iii) a vehicle.

Another aspect of this invention is a coated substrate comprising:

a) a substrate; and
b) at least one layer disposed on the substrate comprising:
i) a plurality of CZTS/Se microparticles;
ii) a plurality of particles selected from the group consisting of: CZTS/Se nanoparticles; elemental Cu-, elemental Zn- or elemental Sn-containing particles; binary or ternary Cu-, Zn- or Sn-containing chalcogenide particles; and mixtures thereof.

Descriptions and preferences regarding the CZTS/Se microparticles and plurality of particles are the same as described above for the ink composition.

The substrate can be rigid or flexible. In one embodiment, the substrate comprises: (i) a base; and (ii) optionally, an electrically conductive coating on the base. The base material is selected from the group consisting of glass, metals, ceramics, and polymeric films. Suitable base materials include metal foils, plastics, polymers, metalized plastics, glass, solar glass, low-iron glass, green glass, soda-lime glass, metalized glass, steel, stainless steel, aluminum, ceramics, metal plates, metalized ceramic plates, and metalized polymer plates. In some embodiments, the base material comprises a filled polymer (e.g., a polyimide and an inorganic filler). In some embodiments, the base material comprises a metal (e.g., stainless steel) coated with a thin insulating layer (e.g., alumina).

Suitable electrically conductive coatings include metal conductors, transparent conducting oxides, and organic conductors. Of particular interest are substrates of molybdenum-coated soda-lime glass, molybdenum-coated polyimide films, and molybdenum-coated polyimide films further comprising a thin layer of a sodium compound (e.g., NaF, Na₂S, or Na₂Se).

Ink Deposition.

The ink is disposed on a substrate to provide a coated substrate by solution-based coating or printing techniques, including spin-coating, spray-coating, dip-coating, rod-coating, drop-cast coating, roller-coating, slot-die coating, draw-down coating, ink-jet printing, contact printing, gravure printing, flexographic printing, and screen printing. The coating can be dried by evaporation, by applying vacuum, by heating, or by combinations thereof. In some embodiments, the substrate and disposed ink are heated at a temperature from 80-350° C., 100-300° C., 120-250° C., or 150-190° C. to remove at least a portion of the solvent, if present, by-products, and volatile capping agents. The drying step can be a separate, distinct step, or can occur as the substrate and precursor ink are heated in an annealing step.

Coated Substrate.

In some embodiments, the molar ratio of Cu:Zn:Sn in the coating on the substrate is about is 2:1:1. In other embodiments, the molar ratio of Cu to (Zn+Sn) is less than one. In some embodiments, the plurality of particles comprises or consists essentially of CZTS/Se nanoparticles. In other embodiments, the molar ratio of Zn:Sn is greater than one. In some embodiments, the plurality of particles comprises or consists essentially of elemental Cu-, Zn- or Sn-containing particles. In some embodiments, the plurality of particles comprises or consists essentially of binary or ternary Cu-, Zn- or Sn-containing chalcogenide particles. In some embodiments, the at least one layer of the coated substrate consists essentially of CZTS/Se microparticles and CZTS/Se nanoparticles.

The particle sizes in the at least one layer can be determined by techniques such as electron microscopy. In some embodiments, the CZTS/Se microparticles of the coated substrate have an average longest dimension of at least about 0.5, 0.6, 0.7, 0.8, 0.9, 1.0, 1.1, 1.2, 1.3, 1.4, 1.5, 1.6, 1.7, 1.8, 1.9, 2.0, 3.0, 4.0, 5.0, 7.5, 10, 15, 20, 25 or 50 microns, and the plurality of particles of the coated substrate have an average longest dimension of less than about 10, 7.5, 5.0, 4.0, 3.0, 2.0, 1.5, 1.0, 0.75, 0.5, 0.4, 0.3, 0.2, or 0.1 micron(s). In some embodiments, the plurality of particles comprise or consist essentially of nanoparticles.

In some embodiments, the difference between the average longest dimension of the CZTS/Se microparticles of the coated substrate and the average thickness of the at least one layer is at least about 0.1, 0.2, 0.3, 0.4, 0.5, 0.75, 1.0, 1.5, 2.0, 2.5, 3.0, 5.0, 10.0, 15.0, 20.0 or 25.0 microns. In some embodiments, the average longest dimension of the CZTS/Se microparticles of the coated substrate is greater than the average thickness of the at least one layer.

As measured by profilometry, Ra (average roughness) is the arithmetic average deviation of roughness and Wa (average waviness) is the arithmetic average deviation of waviness from the mean line within the assessment length. In some embodiments, the average longest dimension of the CZTS/Se microparticles of the coated substrate is less than the average thickness of the at least one layer and the plurality of particles of the coated substrate are nanoparticles having an average longest dimension of less than about 500 nm, 400 nm, 300 nm, 250 nm, 200 nm, 150 nm, or 100 nm, as determined by electron microscopy. In some embodiments, the average longest dimension of the CZTS/Se microparticles of the coated substrate is less than the average thickness of the at least one layer, the plurality of particles of the coated substrate are nanoparticles, and the Ra of the at least one layer is less than about 1 micron, 0.9 micron, 0.8 micron, 0.7 micron, 0.6 micron, 0.5 micron, 0.4 micron or 0.3 micron, as measured by profilometry. In some embodiments, the Wa of the at least one layer is less than about 1 micron, 0.9 micron, 0.8 micron, 0.7 micron, 0.6 micron, 0.5 micron, 0.4 micron, 0.3 micron, 0.2 micron, or 0.1 micron, as measured by profilometry.

Annealing.

In some embodiments, the coated substrate is heated at about 100-800° C., 200-800° C., 250-800° C., 300-800° C., 350-800° C., 400-650° C., 450-600° C., 450-550° C., 450-525° C., 100-700° C., 200-650° C., 300-600° C., 350-575° C., or 350-525° C. In some embodiments, the coated substrate is heated for a time in the range of about 1 min to about 48 h; 1 min to about 30 min; 10 min to about 10 h; 15 min to about 5 h; 20 min to about 3 h; or, 30 min to about 2 h. Typically, the annealing comprises thermal processing, rapid thermal processing (RTP), rapid thermal annealing (RTA), pulsed thermal processing (PTP), laser beam exposure, heating via IR lamps, electron beam exposure, pulsed electron beam processing, heating via microwave irradiation, or combinations thereof. Herein, RTP refers to a technology that can be used in place of standard furnaces and involves single-wafer processing, and fast heating and cooling rates. RTA is a subset of RTP, and consists of unique heat treatments for different effects, including activation of dopants, changing substrate interfaces, densifying and changing states of films, repairing damage, and moving dopants. Rapid thermal anneals are performed using either lamp-based heating, a hot chuck, or a hot plate. PTP involves thermally annealing structures at extremely high power densities for periods of very short duration, resulting, for example, in defect reduction. Similarly, pulsed electron beam processing uses a pulsed high energy electron beam with short pulse duration. Pulsed processing is useful for processing thin films on temperature-sensitive substrates. The duration of the pulse is so short that little energy is transferred to the substrate, leaving it undamaged.

In some embodiments, the annealing is carried out under an atmosphere comprising: an inert gas (nitrogen or a Group VIIIA gas, particularly argon); optionally hydrogen; and optionally, a chalcogen source such as selenium vapor, sulfur vapor, hydrogen sulfide, hydrogen selenide, diethyl selenide, or mixtures thereof. The annealing step can be carried out under an atmosphere comprising an inert gas, provided that the molar ratio of total chalcogen to (Cu+Zn+Sn) in the coating is greater than about 1. If the molar ratio of total chalcogen to (Cu+Zn+Sn) is less than about 1, the annealing step is carried out in an atmosphere comprising an inert gas and a chalcogen source. In some embodiments, at least a portion of the chalcogen present in the coating (e.g., S) can be exchanged (e.g., S can be replaced by Se) by conducting the annealing step in the presence of a different chalcogen (e.g., Se). In some embodiments, annealings are conducted under a combination of atmospheres. For example, a first annealing is carried out under an inert atmosphere and a second annealing is carried out in an atmosphere comprising an inert gas and a chalcogen source as described above, or vice versa. In some embodiments, the annealing is conducted with slow heating and/or cooling steps, e.g., temperature ramps and declines of less than about 15° C. per min, 10° C. per min, 5° C. per min, 2° C. per min, or 1° C. per min. In other embodiments, the annealing is conducted with rapid and/or cooling steps, e.g., temperature ramps and declines of greater than about 15° C. per min, 20° C. per min, 30° C. per min, 45° C. per min, or 60° C. per min.

Additional Layers.

In some embodiments, the coated substrate further comprises one or more additional layers. These one or more layer(s) can be of the same composition as the at least one layer or can differ in composition. In some embodiments, particularly suitable additional layer(s) comprise CZTS/Se precursors selected from the group consisting of: CZTS/Se molecular precursors, CZTS/Se nanoparticles, elemental Cu-, Zn- or Sn-containing nanoparticles; binary or ternary Cu-, Zn- or Sn-containing chalcogenide nanoparticles; and mixtures thereof. In some embodiments, the one or more additional layer(s) are coated on top of the at least one layer. The top-coated additional layer(s) can serve to planarize the surface of the at least one layer or fill in voids in the at least one layer. In some embodiments, the one or more additional layer(s) are coated prior to coating the at least one layer. The one or more additional layer(s) serve as underlayers that can improve the adhesion of the at least one layer and prevent any shorts that might result from voids in the at least one layer. In some embodiments, the additional layers are coated both prior to and subsequent to the coating of the at least one layer.

In some embodiments, a soft-bake step and/or annealing step occurs between coating the at least one layer and the one or more additional layer(s).

### Films

Another aspect of this invention is a film comprising:

a) an inorganic matrix; and
b) CZTS/Se microparticles characterized by an average longest dimension of 0.5-200 microns, wherein the microparticles are embedded in the inorganic matrix.

CZTS/Se Composition.

An annealed film comprising CZTS/Se is produced by the above annealing processes. In some embodiments, the coherent domain size of the CZTS/Se film is greater than about 30 nm, 40 nm, 50 nm, 60 nm, 70 nm, 80 nm, 90 nm, or 100 nm, as determined by XRD. In some embodiments, the molar ratio of Cu:Zn:Sn is about 2:1:1 in the annealed film. In other embodiments, the molar ratio of Cu to (Zn+Sn) is less than one, and, in other embodiments, a molar ratio of Zn to Sn is greater than one in an annealed film comprising CZTS/Se.

In some embodiments, the annealed film comprises CZTS/Se microparticles embedded in an inorganic matrix. In some embodiments, the inorganic matrix comprises or consists essentially of CZTS/Se or CZTS/Se particles. In some embodiments, the matrix comprises inorganic particles wherein the average longest dimension of the microparticles is longer the average longest dimension of the inorganic particles.

The composition and planar grain sizes of the annealed film, as determined by electron microscopy and EDX measurements, can vary depending on the ink composition, processing, and annealing conditions. According to these methods, in some embodiments, the microparticles are indistiguishable from the grains of the inorganic matrix in terms of size and/or composition, and in other embodiments, the microparticles are distinguishable from the grains of the inorganic matrix in terms of size and/or composition. In some embodiments, the planar grain size of the matrix is at least about 0.1, 0.2, 0.3, 0.4, 0.5, 0.6, 0.7, 0.8, 0.9, 1.0, 1.1, 1.2, 1.3, 1.4, 1.5, 1.6, 1.7, 1.8, 1.9, 2.0, 2.5, 3.0, 3.5, 4.0, 4.5, 5.0, 7.5, 10, 15, 20, 25 or 50 microns. In some embodiments, the CZTS/Se microparticles have an average longest dimension of at least about 0.5, 0.6, 0.7, 0.8, 0.9, 1.0, 1.1, 1.2, 1.3, 1.4, 1.5, 1.6, 1.7, 1.8, 1.9, 2.0, 3.0, 3.5, 4.0, 5.0, 7.5, 10, 15, 20, 25 or 50 microns. In some embodiments, the difference between the average longest dimension of the CZTS/Se microparticles and the planar grain size of the inorganic matrix is at least about 0.1, 0.2, 0.3, 0.4, 0.5, 0.75, 1.0, 1.5, 2.0, 2.5, 3.0, 5.0, 7.5, 10.0, 15.0, 20.0 or 25.0 microns. In various embodiments, the average longest dimension of the microparticles is less than, greater than, or equivalent to the planar grain size of the inorganic matrix.

In various embodiments in which both the CZTS/Se microparticles and the inorganic matrix consist essentially of CZTS/Se, there can be differences in the composition of the CZTS/Se microparticles and the inorganic matrix. The differences can be due to differences in one or more of: (a) the fraction of chalcogenide present as sulfur or selenium in the CZTS/Se, (b) the molar ratio of Cu to (Zn+Sn); (c) the molar ratio of Zn to Sn; (d) the molar ratio of total chalcogen to (Cu+Zn+Sn); (e) the amount and type of dopants; and (e) the amount and type of trace impurities. In some embodiments, the composition of the matrix is given by Cu₂ZnSnSₓSe₄₋ₓ, where 0≦x≦4, and the composition of the microparticles is given by Cu₂ZnSnS_{y}Se_{4-y}, where 0≦y≦4, and the difference between x and y is at least about 0.1, 0.2, 0.3, 0.4, 0.5, 0.75, 1.0, 1.25, 1.5, 1.75, or 2.0. In some embodiments, the molar ratio of Cu to (Zn+Sn) of the CZTS/Se microparticles is MR1 and the molar ratio of Cu to (Zn+Sn) of the CZTS/Se matrix is MR2, and the difference between MR1 and MR2 is at least about 0.1, 0.2, 0.3, 0.4, or 0.5. In some embodiments, the molar ratio of Zn to Sn of the CZTS/Se microparticles is MR3 and the molar ratio of Zn to Sn of the CZTS/Se matrix is MR4, and the difference between MR3 and MR4 is at least about 0.1, 0.2, 0.3, 0.4, or 0.5. In some embodiments, the molar ratio of total chalcogen to (Cu+Zn+Sn) of the CZTS/Se microparticles is MR5 and the molar ratio of total chalcogen to (Cu+Zn+Sn) of the CZTS/Se matrix is MR6, and the difference between MR5 and MR6 is at least about 0.1, 0.2, 0.3, 0.4, or 0.5. In some embodiments, a dopant is present in the film, and the difference between the wt % of the dopant in the CZTS/Se microparticles and in the inorganic matrix is at least about 0.05, 0.1, 0.2, 0.3, 0.4, 0.5, 0.75, or 1 wt %. In some embodiments, dopants comprise an alkali metal (e.g., Na) or Sb. In some embodiments, a trace impurity is present in the film, and the difference between the wt % of the impurity in the CZTS/Se microparticles and in the inorganic matrix is at least about 0.05, 0.1, 0.2, 0.3, 0.4, 0.5, 0.75, or 1 wt %. In some embodiments, trace impurities comprise one or more of: C, O, Ca, Al, W, Fe, Cr, and N.

In some embodiments, the difference between the average longest dimension of the CZTS/Se microparticles and the thickness of the annealed film is at least about 0.1, 0.2, 0.3, 0.4, 0.5, 0.75, 1.0, 1.5, 2.0, 2.5, 3.0, 5.0, 10.0, 15.0, 20.0 or 25.0 microns. In some embodiments, the average longest dimension of the CZTS/Se microparticles is less than the average thickness of annealed film. In some embodiments, the average longest dimension of the CZTS/Se microparticles is less than the average thickness of the annealed film, and the Ra of the annealed film is less than about 1 micron, 0.9 micron, 0.8 micron, 0.7 micron, 0.6 micron, 0.5 micron, 0.4 micron, 0.3 micron, 0.2 micron, 0.1 micron, 0.075 micron, or 0.05 micron, as measured by profilometry. In some embodiments, the average longest dimension of the CZTS/Se microparticles is greater than the average thickness of the annealed film.

It has been found that CZTS/Se can be formed in high yield during the annealing step, as determined by XRD or XAS. In some embodiments, the annealed film consists essentially of CZTS/Se, according to XRD analysis or XAS. In some embodiments, (a) at least about 90%, 95%, 96%, 97%, 98%, 99% or 100% of the copper is present as CZTS/Se in the annealed film, as determined by XAS. This film can be further characterized by: (b) at least about 80%, 85%, 90%, 95%, 96%, 97%, 98%, 99% or 100% of the zinc is present as CZTS/Se, as determined by XAS; and/or (c) at least about 90%, 95%, 96%, 97%, 98%, 99% or 100% of the tin is present as CZTS/Se, as determined by XAS.

Coating and Film Thickness.

By varying the ink concentration and/or coating technique and temperature, layers of varying thickness can be coated in a single coating step. In some embodiments, the coating thickness can be increased by repeating the coating and drying steps. These multiple coatings can be conducted with the same ink or with different inks. As described above, wherein two or more inks are mixed, the coating of multiple layers with different inks can be used to fine-tune stoichiometry and purity of the CZTS/Se films by fine-tuning Cu to Zn to Sn ratios. Soft-bake and annealing steps can be carried out between the coating of multiple layers. In these instances, the coating of multiple layers with different inks can be used to create gradient layers, such as layers that vary in the S/Se ratio. The coating of multiple layers can also be used to fill in voids in the at least one layer and planarize or create an underlayer to the at least one layer, as described above.

The annealed film typically has an increased density and/or reduced thickness versus that of the wet precursor layer. In some embodiments, the film thicknesses of the dried and annealed coatings are 0.1-200 microns; 0.1-100 microns; 0.1-50 microns; 0.1-25 microns; 0.1-10 microns; 0.1-5 microns; 0.1-3 microns; 0.3-3 microns; or 0.5-2 microns.

Purification of Coated Layers and Films.

Application of multiple coatings, washing the coating, and/or exchanging capping agents can serve to reduce carbon-based impurities in the coatings and films. For example, after an initial coating, the coated substrate can be dried and then a second coating can be applied and coated by spin-coating. The spin-coating step can wash organics out of the first coating. Alternatively, the coated film can be soaked in a solvent and then spun-coated to wash out the organics. Examples of useful solvents for removing organics in the coatings include alcohols, e.g., methanol or ethanol, and hydrocarbons, e.g., toluene. As another example, dip-coating of the substrate into the ink can be alternated with dip-coating of the coated substrate into a solvent bath to remove impurities and capping agents. Removal of non-volatile capping agents from the coating can be further facilitated by exchanging these capping agents with volatile capping agents. For example, the volatile capping agent can be used as the washing solution or as a component in a bath. In some embodiments, a layer of a coated substrate comprising a first capping agent is contacted with a second capping agent, thereby replacing the first capping agent with the second capping agent to form a second coated substrate. Advantages of this method include film densification along with lower levels of carbon-based impurities in the film, particularly if and when it is later annealed. Alternatively, binary sulfides and other impurities can be removed by etching the annealed film using techniques such as those used for CIGS films.

### Preparation of Devices, Including Thin-Film Photovoltaic Cells

Another aspect of this invention is a process for preparing a photovoltaic cell comprising a film comprising CZTS/Se microparticles characterized by an average longest dimension of 0.5-200 microns, wherein the microparticles are embedded in an inorganic matrix.

Various embodiments of the film are the same as described above. In some embodiments, the film is the absorber or buffer layer of a photovoltaic cell.

Various electrical elements can be formed, at least in part, by the use of the inks and processes described herein. One aspect of this invention provides a process for making an electronic device that can be prepared by depositing one or more layers in layered sequence onto the annealed coating of the substrate. The layers can be selected from the group consisting of: conductors, semiconductors, and insulators.

Another aspect of this invention provides a process for manufacturing thin-film photovoltaic cells comprising CZTS/Se. A typical photovoltaic cell includes a substrate, a back contact layer (e.g., molybdenum), an absorber layer (also referred to as the first semiconductor layer), a buffer layer (also referred to as the second semiconductor layer), and a top contact layer. The photovoltaic cell can also include an electrode pad on the top contact layer, and an anti-reflective (AR) coating on the front (light-facing) surface of the substrate to enhance the transmission of light into the semiconductor layer. The buffer layer, top contact layer, electrode pads and antireflective layer can be deposited onto the annealed CZTS/Se film.

In one embodiment, a photovoltaic device can be prepared by depositing the following layers in layered sequence onto the annealed coating of the substrate having an electrically conductive layer present: (i) a buffer layer; (ii) a transparent top contact layer, and (iii) optionally, an antireflective layer. In yet another embodiment, the process provides a photovoltaic device and comprises disposing one or more layers selected from the group consisting of buffer layers, top contact layers, electrode pads, and antireflective layers onto the annealed CZTS/Se film. In some embodiments, construction and materials for these layers are analogous to those of a CIGS photovoltaic cell. Suitable substrate materials for the photovoltaic cell substrate are as described above.

### Industrial Utility

Advantages of the inks of the present invention are numerous: 1. The copper, zinc- and tin-containing elemental and chalcogenide particles are easily prepared and, in some cases, commercially available. 2. Combinations of the CZTS/Se, elemental and chalcogenide particles, particularly nanoparticles, can be prepared that form stable dispersions that can be stored for long periods without settling or agglomeration, while keeping the amount of dispersing agent in the ink at a minimum. 3. The incorporation of elemental particles in the ink can minimize cracks and pinholes in the films and lead to the formation of annealed CZTS films with large grain size. 4. The overall ratios of copper, zinc, tin and chalcogenide in the precursor ink, as well as the sulfur/selenium ratio, can be easily varied to achieve optimum performance of the photovoltaic cell. 5. The use of nanoparticles enables lower annealing temperatures and denser film packing, while the incorporation of microparticles enables the inclusion of larger grain sizes in the film, even with relatively low annealing temperatures. 6. The ink can be prepared and deposited using a small number of operations and scalable, inexpensive processes. 7. Coatings derived from the ink described herein can be annealed at atmospheric pressure. Moreover, for certain ink compositions, only an inert atmosphere is required. For other ink compositions, the use of H₂S or H₂Se is not required to form CZTS/Se, since sulfurization or selenization can be achieved with sulfur or selenium vapor.

In some instances, the film of the present invention comprises semiconductor microparticles embedded in an inorganic matrix. Solar cells made from these semiconductor layers potentially have all of the advantages of monograin layer solar cells while incorporating an inorganic matrix with potentially greater heat and light stability as compared to the organic matrix of traditional monograin solar cells. Another advantage is that films of the present invention are less prone to cracking.

### Characterization

Useful analytical techniques for characterizing the composition, size, size distribution, density, and crystallinity of the metal chalcogenide nanoparticles, crystalline multinary-metal chalcogenide particles and layers of the present invention include XRD, XAFS (XAS), EDAX, ICP-MS, DLS, AFM, SEM, TEM, ESC, and SAX.

The following is a list of abbreviations used above and in the Examples:

| Abbreviation | Description |
|---|---|
| XRD | X-Ray Diffraction |
| TEM | Transmission Electron Microscopy |
| ICP-MS | Inductively Coupled Plasma Mass Spectrometry |
| AFM | Atomic Force Microscopy |
| DLS | Dynamic Light Scattering |
| SEM | Scanning Electron Microscopy |
| SAXS | Small Angle X-ray Scattering |
| EDX | Energy-Dispersive X-ray Spectroscopy |
| XAFS | X-Ray Absorption Fine Structure |
| PSD | Particle Size Distribution |
| CIGS | Copper-Indium-Gallium-Sulfo-di-selenide |
| CZTS | Copper Zinc Tin Sulfide (Cu₂ZnSnS₄) |
| CZTSe | Copper Zinc Tin Selenide (Cu₂ZnSnSe₄) |
| CZTS/Se | All possible combinations of CZTS and CZTSe |
| CTS | Copper Tin Sulfide (Cu₂SnS₃) |
| CTSe | Copper Tin Selenide (Cu₂SnSe₃) |
| CTS/Se | All possible combinations of CTS and CTSe |
| RTA | Rapid Thermal Annealing |
| EA | Ethanolamine |
| DEA | Diethanolamine |
| TEA | Triethanolamine |
| TMA | Trimethanolamine |
| HMT | Hexamethylenetetramine |
| ED | Ethylene diamine |
| EDTA | Ethylenediamine tetraacetic acid |

### EXAMPLES

### General

Materials.

Unless noted otherwise, reagents were purchased from commercial sources and used as received.

Annealing of Coated Substrates in a Tube Furnace.

Annealings were carried out either under an inert atmosphere (nitrogen or argon) or under an inert atmosphere comprising sulfur. Annealings under an inert atmosphere were carried out in either a single-zone Lindberg/Blue (Ashville, N.C.) tube furnace equipped with an external temperature controller and a one-inch quartz tube, or in a Lindberg/Blue three-zone tube furnace (Model STF55346C) equipped with a three-inch quartz tube. A gas inlet and outlet were located at opposite ends of the tube, and the tube was purged with the inert gas while heating and cooling. The coated substrates were placed on quartz plates or boats inside of the tube.

Annealings under a sulfur atmosphere were carried out in the single-zone furnace in the one-inch tube. A 3-inch long ceramic boat was loaded with 2.5 g of elemental sulfur and placed near the nitrogen inlet, outside of the direct heating zone. The coated substrates were placed on quartz plates inside the tube.

When annealing under selenium, the substrates were placed inside of a graphite box (Industrial Graphite Sales, Harvard, Ill.) with a lid with a center hole in it of 1 mm in diameter. The box dimensions were 5″ length×1.4″ width×0.625″ height with a wall and lid thickness of 0.125″. The selenium was placed in small ceramic boats within the graphite box.

### Details of the Procedures Used for Device Manufacture

Mo-Sputtered Substrates.

Substrates for photovoltaic devices were prepared by coating a SLG substrate with a 500 nm layer of patterned molybdenum using a Denton Sputtering System. Deposition conditions were: 150 watts of DC Power, 20 sccm Ar, and 5 mT pressure. Alternatively, Mo-sputtered SLG substrates were purchased from Thin Film Devices, Inc. (Anaheim, Calif.).

Cadmium Sulfide Deposition.

CdSO₄ (12.5 mg, anhydrous) was dissolved in a mixture of nanopure water (34.95 mL) and 28% NH₄OH (4.05 mL). Then a 1 mL aqueous solution of 22.8 mg thiourea was added rapidly to form the bath solution. Immediately upon mixing, the bath solution was poured into a double-walled beaker (with 70° C. water circulating between the walls), which contained the samples to be coated. The solution was continuously stirred with a magnetic stir bar. After 23 minutes, the samples were taken out, rinsed with and then soaked in nanopure water for an hour. The samples were dried under a nitrogen stream and then annealed under a nitrogen atmosphere at 200° C. for 2 min.

Insulating ZnO and AZO Deposition.

A transparent conductor was sputtered on top of the CdS with the following structure: 50 nm of insulating ZnO (150 W RF, 5 mTorr, 20 sccm) followed by 500 nm of Al-doped ZnO using a 2% Al₂O₃, 98% ZnO target (75 or 150 W RF, 10 mTorr, 20 sccm).

ITO Transparent Conductor Deposition.

A transparent conductor was sputtered on top of the CdS with the following structure: 50 nm of insulating ZnO [100 W RF, 20 mTorr (19.9 mTorr Ar+0.1 mTorr O₂)] followed by 250 nm of ITO [100 W RF, 12 mTorr (12 mTorr Ar+5×10⁻⁶ Torr O₂)]. The sheet resistivity of the resulting ITO layer is approximately 30 ohms per square.

Deposition of Silver Lines.

Silver was deposited at 150 WDC, 5 mTorr, 20 sccm Ar, with a target thickness of 750 nm.

IV Analysis.

Current (I) versus voltage (V) measurements were performed on the samples using two Agilent 5281B precision medium power SMUs in a E5270B mainframe in a four point probe configuration. Samples were illuminated with an Oriel 81150 solar simulator under 1 sun AM 1.5G.

XRD Analysis.

Powder X-ray diffraction was used for the identification of crystalline phases. Data were obtained with a Philips X'PERT automated powder diffractometer, Model 3040. The diffractometer was equipped with automatic variable anti-scatter and divergence slits, X'Celerator RTMS detector, and Ni filter. The radiation was CuK(alpha) (45 kV, 40 mA). Data were collected at room temperature from 4 to 120°. 2-theta; using a continuous scan with an equivalent step size of 0.02°; and a count time of from 80 sec to 240 sec per step in theta-theta geometry. Thin film samples were presented to the X-ray beam as made. MDI/Jade software version 9.1 was used with the International Committee for Diffraction Data database PDF4+2008 for phase identification and data analysis.

Particle Size Distribution (PSD).

The PSD was measured with a Beckman Coulter LS13320 using laser diffraction to determine the volume distribution of a field of particles. An aliquot of the powder (˜0.1 g) was mixed 1 drop of Surfynol® (a surfactant to promote wetting) and 20 mL of deionized water and sonified by ultrasonic probe for one minute. A portion of this was added to the instrument which was also filled with deionized water. Two repeat runs were made as a check on sample stability and on instrument reproducibility

SAXS Analysis.

Determination of particle sizes and distributions by SAXS was carried out using a USAXS double crystal, Bonse-Hart, from Rigaku (http://www.rigaku.com/saxs/ultra.html). Samples were analyzed as a single layer (˜50 μm thick) of crystallites on sticky tape. Desmearing and analysis were conducted as contained in a standard package for IGOR.

Synthesis of CZTS Crystals.

Copper(II) sulfide (4.35 g, 0.0455 mol), zinc(II) sulfide (2.22 g, 0.0228 mol), and tin(IV) sulfide (4.16 g, 0.0228 mol) were mixed together by shaking for 15 min. The mixture was placed in a 20 mL alumina boat, which was then put into a tube furnace with nitrogen flow. The boat was heated from ambient temperature to 800° C. in 15 min, and kept at this temperature for 1 day. The sample was cooled down to ambient temperature, ground, and then placed back into the boat and the tube furnace under nitrogen flow. The heating cycle was then repeated. This procedure was repeated 4 times, giving a total heating time of 5 days. The sample was analyzed by XRD to confirm presence of CZTS crystals. In some instances, the crystals were ground to provide a fine powder and sieved through a 345 micron mesh. In some instances, the crystals were media-milled to provide microparticles with D50 of 1.0078 micron and D95 of 2.1573 microns, according to PSD analysis.

Synthesis of CZTSe Microparticles.

Micron-sized CZTSe particles were synthesized via the flux approach from CuSe (4.55 g, 0.032 mol), ZnSe (2.30 g, 0.016 mol), SnSe (3.15 g, 0.016 mol) and CsCl (20.00 g). The binary selenides, together with CsCl, were mixed together in a glove box by shaking for 15 min and then placed into a 20 mL alumina boat. The boat was loaded into a tube furnace with nitrogen flow and heated at 750° C. for 5 days. The furnace was cooled to room temperature, and the boat was immersed in 500 mL of distilled water. Black crystalline material was filtered, washed with an additional 500 mL of water, and dried at 1 mm vacuum for 12 h. The flux synthesis was repeated twice and the products combined to prepare enough material for the next step. The resulting 12.30 g of crystalline CZTSe were milled with 200.55 g of YTZ (yttria-treated zirconia) and with 50.01 g of iso-propanol for 17 days in a U.S. Stoneware roller machine (East Palestine, Ohio). The particle sizes of CZTSe were found to be 1.4591 microns (D₉₀) and 0.6459 micron (D₅₀). The YTZ media were separated from the CZTSe suspension in iso-propanol. Then, solvent was removed under 1 mm vacuum, and the residual powder was sieved through a 325 mesh screen. The CZTSe structure of the product was confirmed by XRD analysis.

Aqueous Synthesis of CZTS Particles.

Aqueous stock solutions were prepared in nanopure water. Solutions of CuSO₄ (3.24 mmol; 0.4 M), ZnSO₄ (1.4 mmol; 0.8 M), and SnCl₄(1.575 mmol, 0.7 M) were mixed together in a round bottom flask equipped with a stir bar. Next, solutions of NH₄NO₃ (1 mmol; 0.4 M) and triethanolamine (TEA, 3.8 mmol, 3.7 M) were sequentially added to the reaction mixture. Sulfuric acid was used to adjust the pH to 1, and the reaction mixture was stirred for 30 min, followed by the addition of aqueous thioacetamide (TAA, 27.6 mmol, 0.4 M). The flask was placed in a hot water bath with magnetic stirring and the reaction temperature was maintained at 80° C. for 2.5 hr to provide a black suspension. Next, the water bath was removed, and the flask was allowed to cool to room temperature. The resulting precipitate was collected via decantation/centrifugation. The solids were washed three times with water, and then portions of the material were dried overnight in a vacuum oven at 45° C. to provide a black powder that represents the as-synthesized mixture of Cu, Zn, and Sn sulfide nanoparticles. The nanoparticles were placed in a quartz boat and were thermally treated at 550° C. under a nitrogen and sulfur atmosphere in a 2-inch tube furnace for 2 hr to provide high purity CZTS particles with a kesterite structure, as confirmed by XRD, HR-TEM, XAS and XRF. Analysis by SAXS indicated the formation of particles ranging from 0.1 to 1.0 micron in size.

Preparation of Oleylamine-Coated CZTS Nanoparticles.

In the following procedure, all metal salts and elemental sulfur were dissolved in oleylamine at 100° C.: A solution of 80 mg (0.586 mmol) of zinc chloride in 10 mL of oleylamine and a solution of 102 mg (0.587 mmol) of tin(II) chloride in 10 mL of oleylamine were mixed with stirring and heated to 110° C. under an Ar atmosphere. After 5 min, a solution of 77 mg (0.777 mmol) of cuprous chloride in 10 mL of oleylamine was added to the reaction mixture, and the resulting solution was stirred for an additional 5 min. Then, a solution of 163 mg (5.08 mmol) of sulfur dissolved in 10 mL of oleylamine was added, and the reaction temperature was raised to 230° C. at a rate of 10° C./min. The system was maintained at this temperature for 10 min, and then the heat was turned off. The reaction was allowed to cool to room temperature with stirring, with the heating block remaining in place as it cooled. Following cooling, 80 mL of ethanol was added to the reaction mixture. The particles were collected via centrifugation and decanting of the solvent. The presence of CZTS was determined by XRD. The particle size was determined using DLS and TEM and AFM. The particles ranged between 1-10 nm in size.

Synthesis of CuS Nanoparticles.

A solution of copper (II) chloride (1.3445 g, 10 mmol) and trioctylphosphine oxide (11.6 g, 30 mmol) in 40 mL of oleylamine was heated at 220° C. under a nitrogen atmosphere with continuous mechanical stirring for 1 hr, followed by rapid addition of a solution of sulfur (0.3840 g, 12 mmol) in 10 mL of oleylamine. The reaction mixture was maintained at 220° C. for 2 min, and then cooled in an ice-water bath. Hexane (30 mL) was added to the reaction mixture to disperse the nanoparticles. Then, 60 mL of ethanol was added to the mixture to precipitate the nanoparticles. The nanoparticles were collected by centrifuging the mixture and decanting the supernatant, and then the CuS nanoparticles were dried in a vacuum desiccator overnight. The CuS covellite structure was determined by XRD.

Synthesis of Cu₂S Nanoparticles.

A solution of copper nitrate (Cu(NO₃)₂.2.5H₂O, 0.2299 g, 1 mmol), sodium acetate (0.8203 g, 10 mmol), and glacial acetic acid (0.6 mL) in 20 mL of water was mixed with 1-dodecanethiol (3 mL) at room temperature, in a 400 mL glass-lined Hastelloy C shaker tube. The reaction mixture was heated at 200° C. under 250 psig of nitrogen for 6 hr. The reaction mixture was cooled, and the colorless aqueous phase at the bottom of the tube was discarded. Ethanol (20 mL) was added to the dark brown oil phase to precipitate the coated nanoparticles, which were collected via centrifugation. According to XRD and TEM, the coated Cu₂S nanoparticles are roughly spherical, with an average diameter of 10-15 nm.

Synthesis of SnS Nanoparticles.

A solution of tin(IV) chloride (2.605 g, 10 mmol) and trioctylphosphine oxide (11.6 g, 30 mmol) in 40 mL oleylamine was heated at 220° C. under a nitrogen atmosphere with continuous mechanical stirring for 15 min, followed by rapid addition of a solution of sulfur (0.3840 g, 12 mmol) in 10 mL of oleylamine. The reaction mixture was maintained at 220° C. for 3 min and then cooled in an ice-water bath. Hexane (30 mL) was added to the reaction mixture to disperse the nanoparticles. Then 60 mL of ethanol was added to the mixture to precipitate the nanoparticles. The nanoparticles were collected by centrifuging the mixture and decanting the supernatant, and the SnS nanoparticles were then dried in a vacuum desiccator overnight.

Synthesis of ZnS Nanoparticles.

A solution of ZnCl₂ (3.8164 g, 28 mmol) and trioctylphosphine oxide (32.4786 g, 84 mmol) in 80 mL of oleylamine was heated at 170° C. under a nitrogen atmosphere with continuous mechanical stirring for 1 hr, followed by the rapid addition of a solution of sulfur (0.8960 g, 28 mmol) in 10 mL of oleylamine. The reaction mixture was heated to 320° C. and maintained at this temperature for 75 min, before cooling in an ice-water bath. Hexane (60 mL) was added to the reaction mixture to disperse the nanoparticles. Then, 120 mL of ethanol was added to the mixture to precipitate the nanoparticles. The nanoparticles were collected by centrifuging the mixture and decanting the supernatant, and the ZnS nanoparticles were dried in a vacuum desiccator overnight. The ZnS sphalerite structure was determined by XRD and the size was determined by SEM. According to SEM, the particles were 10-50 nm in diameter.

Synthesis of Coated Cu SnS₃ Nanoparticles.

A solution of CuCl (0.1980 g, 2 mmol), SnCl₄ (0.2605 g, 1 mmol), and trioctylphosphine oxide (2.3 g, 5.95 mmol) in 10 mL of oleylamine was heated at 240° C. under a nitrogen atmosphere with continuous mechanical stirring for 15 min, followed by the addition of sulfur (0.0960 g, 3 mmol) dissolved in 3 mL of oleylamine. The reaction mixture was stirred at 240° C. for 20 minutes. The reaction mixture was cooled rapidly by first submerging the reaction vessel in a room temperature water bath and then in an acetone-dry ice bath (−78° C.) to obtain a solid product. The solid was dissolved in hexane and precipitated in ethanol. The precipitated solid was collected using centrifugation. The process of dissolving in hexane, precipitation with ethanol and centrifugation was repeated twice. The Cu₂SnS₃ structure was determined by XRD. Particle shape and size were determined using SEM and TEM. According to SEM, the particles were 10-50 nm in diameter. According to TEM, the particles were 10-30 nm in diameter.

Removal of the Oxide Layer from Commercial Cu Particles.

Commercial copper nanopowder (99.8%, 1 g, 78 nm, Nanostructured & Amorphous Materials, Inc., Houston, Tex.) was added to a solution containing 10 g citric acid, 1.5 g L-ascorbic acid, 1 mL Citranox (Alconox Inc., White Plains, N.Y.) and 20 mL water. The mixture was sonicated in a bath sonicator at 50° C. for 30 min. The copper nanoparticles were collected by centrifuging and decanting the supernatant. Next, the Cu nanoparticles were washed twice with water and once with ethanol, and then dried in a vacuum desiccator overnight.

### Examples 1A-1D

Examples 1A-1D illustrate the preparation of inks comprising CZTS particles, CuS or Cu nanoparticles, ZnS nanoparticles, and SnS nanoparticles, and the use of these inks to form CZTS films.

CuS, SnS, and ZnS nanoparticles (prepared as described above) were individually dispersed in THF at a concentration of 500 mg nanoparticles per mL THF. Each suspension was sonicated in a bath sonicator for 30 min and then with an ultrasonic probe for 10 min. The CuS and ZnS suspensions were passed through a 1.0 micron syringe filter (Whatman, 1.0 micron GF/B w/GMF); the SnS suspension was passed through a 2.7 micron syringe filter (Whatman, 2.7 micron GF/D w/GMF). These suspensions were used for Examples 1A, 1B, 1C and 1D.

### Example 1A

Portions of the CuS suspension (0.4025 mL), SnS suspension (1.1623 mL), and ZnS suspension (0.4352 mL) were mixed to provide a mixture of CuS, SnS, and ZnS nanoparticles. CZTS microcrystals that had been sieved through a 345 micron mesh (20 mg; prepared as described above) were added to 0.5 mL of the mixture of CuS, SnS, and ZnS nanoparticles. The mixture was then sonicated in a bath sonicator for 20 min. This ink was agitated strongly immediately prior to being drop-coated onto a Mo-coated glass substrate. The coated substrate was annealed in a tube furnace at 550° C. for 1 h under N₂, and then annealed at 500° C. for 2 h in a sulfur/N₂ atmosphere. The annealed sample was etched in a 0.5 M KCN solution at 50° C. for 1 min, rinsed with deionized water, and dried under a nitrogen stream. A second etching step was carried out in a 1.0 M HCl solution for 1 min at room temperature, followed by thorough rinsing with deionized water, and drying under a nitrogen stream. The XRD of the annealed film indicated the presence of essentially pure CZTS.

### Example 1B

Portions of the CuS suspension (0.0826 mL), SnS suspension (0.3078 mL), and ZnS suspension (0.1097 mL) were mixed. CZTS particles (prepared according to the above aqueous synthesis; 15 mg) was added to 0.25 mL of the mixture of CuS, ZnS, and SnS nanoparticles. The mixture was then sonicated in a bath sonicator for 20 min. A Mo-coated glass substrate was coated, annealed and etched according to the procedures of Example 1A. The XRD of the annealed film indicated the presence of essentially pure CZTS.

### Example 1C

Cu nanoparticles (37.5 mg) and portions of the ZnS suspension (0.1860 mL) and the SnS suspension (0.5640 mL) were mixed. CZTS particles (prepared according to the above aqueous synthesis; 15 mg) was added to 0.25 mL of the mixture of Cu, ZnS, and SnS nanoparticles. The resulting mixture was sonicated in a bath sonicator for 20 min. This ink was agitated strongly immediately prior to being spun-coated onto a Mo-coated glass substrate at 1000 rpm for 20 sec, and then at 1500 rpm for 10 sec. The coated substrate was annealed and etched according to the procedures of Example 1A. The XRD of the annealed film indicated the presence of essentially pure CZTS.

### Example 1D

Cu nanoparticles (37.5 mg) and portions of the ZnS suspension (0.1860 mL) and SnS suspension (0.5640 mL) were mixed. CZTS microcrystals that had been sieved through a 345 micron mesh (15 mg; prepared as described above) were added to 0.25 mL of the mixture of Cu, ZnS, and SnS nanoparticles. The resulting mixture was sonicated in a bath sonicator for 20 min. This ink was agitated strongly immediately prior to being spun-coated onto a Mo-coated glass substrate at 1000 rpm for 20 sec, and then at 1500 rpm for 10 sec. The coated substrate was annealed and etched according to the procedures of Example 1A. The XRD of the annealed film indicated the presence of essentially pure CZTS.

### Example 2

This example illustrates the preparation and use of an ink prepared from a mixture of oleylamine CZTS nanoparticles and CZTS particles.

Toluene was added to a centrifuge tube containing the oleylamine CZTS nanoparticles prepared as described above to provide an ink with a final concentration of 200 mg/mL. The ink was bath-sonicated for 9 min, stirred, and then transferred to a vial. An aliquot (2 mL) was mixed with 0.4 g of CZTS particles (prepared as described above in the aqueous synthesis), tip-sonicated for 12 min, and then bar-coated onto a Mo-coated soda-lime glass substrate. The coated substrate was annealed in a nitrogen/sulfur atmosphere for 2 h at 550° C. to generate an annealed film of CZTS, as characterized by XRD.

### Example 3

This example illustrates the preparation and use of an ink prepared from a mixture of coated ZnS and Cu₂SnS₃ nanoparticles and CZTS particles.

Cu₂SnS₃ nanoparticles (0.146 g; prepared as described above) were mixed with 43.8 mg of ZnS nanoparticles in 0.32 g of THF. Next, 0.1 g of CZTS particles prepared according to the aqueous synthesis and 0.69 g of MeOH were added, and the mixture was horn-sonicated for 12 min, then bath sonicated for an additional 10 min. The ink was bar-coated onto a Mo-coated soda-lime glass substrate. The coated substrate was annealed in a sulfur/nitrogen atmosphere for 2 hr at 550° C. to generate a film of CZTS, as characterized by XRD.

### Example 4

This example illustrates the preparation and use of an ink prepared from a mixture of oleylamine CZTS nanoparticles and CZTS crystals.

Toluene was added to a centrifuge tube containing the oleylamine CZTS nanoparticles prepared as described above to provide an ink with a final concentration of 200 mg/mL. The ink was bath-sonicated for 9 min, stirred, and then transferred to a vial. An aliquot (2 mL) was mixed with 0.17 g of CZTS crystals (prepared as described above), then horn-sonicated for 8 min and bath-sonicated for an additional 10 min. The ink was spun-coated at 600 rpm onto a Mo-coated soda-lime glass substrate, which was then placed on a 90° C. hot plate for 1 hr. The coated substrate was then annealed in sulfur/nitrogen atmosphere for 2 hr at 550° C. to generate a film of CZTS, as characterized by XRD.

### Example 5

This example illustrates the preparation and use of an ink prepared from a mixture of oleylamine CZTS nanoparticles and CZTSe microparticles.

The Mo-coated-SLG substrates used in this example were cleaned with acetone, water, methanol, water and dried under a nitrogen stream. Immediately prior to coating with the ink, the Mo substrates were pre-treated with a toluene solution containing 10% hexanethiol via spin-coating.

An ink containing a mixture of oleylamine-coated CZTS nanoparticles was prepared by drying an ˜200 mg pellet of the nanoparticles in an argon stream. Hexanethiol (1.5 mL) was added to the pellet and the resulting mixture was agitated via probe sonication for 5 minutes. Micron-sized CZTSe particles (0.1 g) were mixed with the nanoparticle ink. The ink was then spin-coated onto substrates at 1000 rpm for 60 sec, using 100 micro-L of the ink per substrate. The coated substrates were heat-treated on a hot plate in the following sequence: 175° C., 250° C., 300° C., 250° C. and 175° C. for time intervals of 30 sec, 30 sec, 60 sec, 30 sec and 30 sec, respectively. Another coating was fabricated following the same heating process. Cadmium sulfide, an insulating ZnO layer, an ITO layer, and silver lines were deposited. The resulting device exhibited a PV effect with V_{oc}=384 mV, J_{sc}=−21.83 mA/cm², FF=39.0%, and efficiency=3.27%.

What is claimed is:

1. An ink comprising:
a) a plurality of CZTS/Se microparticles;
b) a plurality of particles selected from the group consisting of: CZTS/Se nanoparticles; elemental Cu-, elemental Zn- or elemental Sn-containing particles; binary or ternary Cu-, Zn- or Sn-containing chalcogenide particles; and mixtures thereof; and
c) a vehicle.

2. The ink of claim 1, wherein at least one of the ink, the plurality of particles or the vehicle have been heat processed at a temperature of greater than about 100° C.

3. The ink of claim 1, wherein the molar ratio of Cu:Zn:Sn is about 2:1:1.

4. The ink of claim 1, wherein the plurality of particles comprises CZTS/Se nanoparticles, binary or ternary Cu-, Zn- or Sn-containing chalcogenide particles, or the ink further comprises an elemental chalcogen.

5. The ink of claim 4, wherein the binary or ternary Cu-, Zn- or Sn-containing chalcogenide particles are selected from the group consisting of: sulfide particles, selenide particles, sulfide/selenide particles, and mixtures thereof; and the elemental chalcogen is sulfur, selenium, or a mixture thereof.

6. The ink of claim 1, wherein the plurality of particles comprises nanoparticles having an average longest dimension of less than about 500 nm, as determined by electron microscopy.

7. The ink of claim 1, wherein the elemental Cu-, elemental Zn- or elemental Sn-containing particles are selected from the group consisting of: Cu particles, Cu—Sn alloy particles, Cu—Zn alloy particles, Zn particles, Zn—Sn alloy particles, Sn particles; and mixtures thereof; and the binary or ternary Cu-, Zn- or Sn-containing chalcogenide particles are selected from the group consisting of: Cu₂S/Se particles, CuS/Se particles, Cu₂Sn(S/Se)₃ particles, Cu₄Sn(S/Se)₄ particles, ZnS/Se particles Sn(S/Se)₂ particles, SnS/Se particles, and mixtures thereof.

8. The ink of claim 1, wherein the CZTS/Se nanoparticles and Cu-, Zn- or Sn-containing chalcogenide particles further comprise an organic capping agent.

9. A coated substrate comprising:
a) a substrate; and
b) at least one layer disposed on the substrate comprising:
i) a plurality of CZTS/Se microparticles;
ii) a plurality of particles selected from the group consisting of: CZTS/Se nanoparticles; elemental Cu-, elemental Zn- or elemental Sn-containing particles; binary or ternary Cu-, Zn- or Sn-containing chalcogenide particles; and mixtures thereof.

10. The coated substrate of claim 9, wherein the molar ratio of Cu:Zn:Sn is about 2:1:1.

11. The coated substrate of claim 9, wherein the plurality of particles comprises CZTS/Se nanoparticles or binary or ternary Cu-, Zn- or Sn-containing chalcogenide particles, or the at least one layer further comprises an elemental chalcogen.

12. The coated substrate of claim 9, wherein the elemental Cu-, elemental Zn- or elemental Sn-containing particles are selected from the group consisting of: Cu particles, Cu—Sn alloy particles, Cu—Zn alloy particles, Zn particles, Zn—Sn alloy particles, Sn particles; and mixtures thereof; and the binary or ternary Cu-, Zn- or Sn-containing chalcogenide particles are selected from the group consisting of: Cu₂S/Se particles, CuS/Se particles, Cu₂Sn(S/Se)₃ particles, Cu₄Sn(S/Se)₄ particles, ZnS/Se particles, Sn(S/Se)₂ particles, SnS/Se particles, and mixtures thereof.

13. The coated substrate of claim 9, wherein the plurality of particles has been heat-processed at a temperature greater than about 100° C.; or the microparticles and plurality of particles have been heat-processed at a temperature greater than about 100° C.

14. A film comprising:
a) an inorganic matrix; and
b) CZTS/Se microparticles characterized by an average longest dimension of 0.5-200 microns, wherein the microparticles are embedded in the inorganic matrix.

15. A photovoltaic device comprising the film of claim 14.
